(19) United States
(12) Patent Application Publication
(10) Pub. No.: US 2015/0263705 A1
(43) Pub. Date: Sep. 17, 2015

(54) SIGNAL TRANSMISSION CIRCUIT AND CLOCK BUFFER

(71) Applicant: KABUSHIKI KAISHA TOSHIBA, Tokyo (JP)

(72) Inventors: Kenji KANAMARU, Yokohama Kanagawa (JP); Katsue KAWAKYU, Kawasaki Kanagawa (JP)

(21) Appl. No.: 14/475,502

(22) Filed: Sep. 2, 2014

(30) Foreign Application Priority Data
Mar. 12, 2014 (JP) 2014-049416

(51) Int. Cl. H03K 3/013

(52) U.S. Cl. CPC H03K 3/013

(57) ABSTRACT

A signal transmission circuit includes an input node through which an input rectangular waveform is supplied, an inverter that generates an inverted input signal, a push-pull circuit that generates an output signal of the signal transmission circuit, a first drive circuit that generates a first drive signal for the push-pull circuit from the inverted input signal and a first adjusted waveform, and a second drive circuit that generates a second drive signal for the push-pull circuit from the inverted input signal and a second adjusted waveform. The first adjusted waveform falls with a first time constant when the input rectangular waveform is high and the second adjusted waveform rises with a second time constant when the input rectangular waveform is low. The output signal of the signal transmission circuit has a rise time correlated to the first adjusted waveform and a fall time correlated to the second adjusted waveform.

### CROSS-REFERENCE TO RELATED APPLICATION

This application is based upon and claims the benefit of priority from Japanese Patent Application No. 2014-049416, filed Mar. 12, 2014, the entire contents of which are incorporated herein by reference.

### FIELD

Embodiments described herein relate generally to a signal transmission circuit and a clock buffer.

### BACKGROUND

A rectangular wave signal includes harmonic components, and thus harmonic noise is generated from a circuit that outputs a rectangular wave signal with a rapid rising or falling edge. Particularly, the occurrence of harmonic noise is a great problem in a clock buffer that buffers a high-speed clock signal.

In order to minimize harmonic noise, linear amplification may be performed by converting a rectangular wave signal into a sinusoidal signal by using a high-speed operational amplifier. However, the high-speed operational amplifier has a problem in that current consumption increases due to a high operation speed.

Additionally, when a high-speed signal transmission circuit is designed, harmonic noise may be minimized by intentionally generating a slow output signal waveform. However, there is a concern that the slow output signal waveform may cause timing delays, that is, a logical change of a high-speed clock signal may not be recognized at the same point in time by circuits receiving the clock signal.

### DESCRIPTION OF THE DRAWINGS

FIG. 1 is a circuit diagram of a signal transmission circuit according to an exemplary embodiment.

FIG. 2 is a signal waveform diagram of each portion of the signal transmission circuit in FIG. 1.

### DETAILED DESCRIPTION

Embodiments provide a signal transmission circuit and a clock buffer capable of minimizing the occurrence of harmonic noise and having high-speed operation.

In general, according to one embodiment, there is provided a signal transmission circuit including an input node through which an input rectangular waveform is supplied, an inverter that generates an inverted input signal, a push-pull circuit that generates an output signal of the signal transmission circuit, a first drive circuit that generates a first drive signal for the push-pull circuit from the inverted input signal and a first adjusted waveform, and a second drive circuit that generates a second drive signal for the push-pull circuit from the inverted input signal and a second adjusted waveform. The first adjusted waveform falls with a first time constant when the input rectangular waveform is high and the second adjusted waveform rises with a second time constant when the input rectangular waveform is low. The output signal of the signal transmission circuit has a rise time correlated to the first adjusted waveform and a fall time correlated to the second adjusted waveform.

Hereinafter, an exemplary embodiment is described with reference to the drawings. In the following exemplary embodiment, characteristic configurations and operations of a signal transmission circuit and a clock buffer are mainly described, but configurations and operations, which are omitted in the following description, may be present in the signal transmission circuit and the clock buffer. These omitted configurations and operations are included in the scope of the exemplary embodiment.

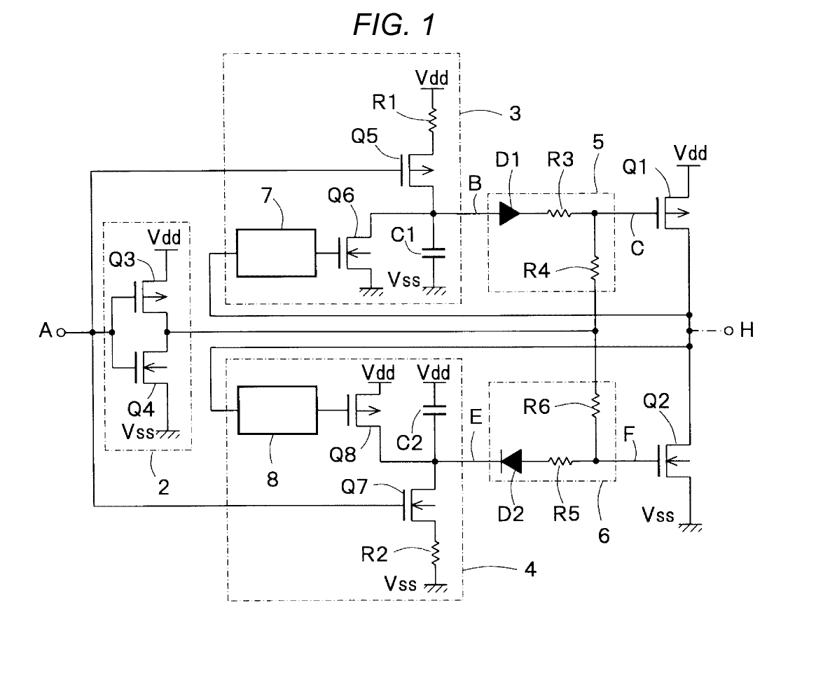

FIG. 1 is a circuit diagram illustrating a signal transmission circuit 1 according to an exemplary embodiment. The signal transmission circuit 1 in FIG. 1 buffers an input signal A, such as a clock signal, and outputs a result thereof, and may be used as a clock buffer. In addition, the input signal A which is sent to the signal transmission circuit 1 in FIG. 1 is not necessarily limited to a clock signal. Any binary digital signal may be sent to the signal transmission circuit 1 in FIG. 1.

The signal transmission circuit 1 in FIG. 1 includes a logic inverter 2, a first waveform adjustment section 3, a second waveform adjustment section 4, a push-pull circuit formed from a PMOS transistor (first MOS transistor) Q1 and an NMOS transistor (second MOS transistor) Q2 with a push-pull configuration, a first gate drive circuit 5, and a second gate drive circuit 6.

The logic inverter 2 generates an inverted input signal. A simple example of the logic inverter 2 is an inverter formed by a PMOS transistor Q3 and an NMOS transistor Q4 that are connected in series to each other between a power supply voltage node Vdd and a ground node Vss.

The first waveform adjustment section 3 operates while the input signal A has first logic level (for example, a low level), and generates a first intermediate signal whose change in a first period is slower than a signal change of the input signal A.

The second waveform adjustment section 4 operates while the input signal A has second logic level (for example, a high level), and generates a second intermediate signal whose change in a second period is slower than a signal change of the input signal A.

The first gate drive circuit 5 controls the gate voltage of the PMOS transistor Q1 based on the first intermediate signal and the inverted input signal. More specifically, the first gate drive circuit 5 controls a gate voltage of the PMOS transistor Q1 so that the PMOS transistor Q1 is weakly in an on-state first, and is then completely in the on-state, when the NMOS transistor Q2 is in an off-state. In other words, based on the first intermediate signal and the inverted input signal, the first gate drive circuit 5 turns off the PMOS transistor Q1 in a period when the input signal A has the first logic (for example, a low level), weakly turns on the PMOS transistor Q1 in a predetermined period with a first turn-on time constant after logic of the input signal A changes from the first logic to the second logic (for example, a high level), and completely turns on the PMOS transistor Q1 after the predetermined period has elapsed.

The second gate drive circuit 6 controls a gate voltage of the NMOS transistor Q2 based on the second intermediate signal and the inverted input signal. More specifically, the second gate drive circuit 6 controls a gate voltage of the NMOS transistor Q2 so that the NMOS transistor Q2 is weakly in the on-state first, and is then completely in the on-state, when the PMOS transistor Q1 is in the off-state. In other words, based on the second intermediate signal and the inverted input signal, the second gate drive circuit 6 turns off the NMOS transistor Q2 in a period when the input signal A has the second logic level (for example, a high level), weakly turns on the NMOS transistor Q2 with a second turn-on time constant in a predetermined period after logic of the input signal A changes from the second logic to the first logic level (for example, a low level), and completely turns on the NMOS transistor Q2 after the predetermined period has elapsed.

Accordingly, an output signal of the signal transmission circuit 1 has a waveform whose rising and falling edges slowly change, but a level thereof is then rapidly changed to a desired signal level, and thus signal delay time is minimized. Therefore, the signal transmission circuit 1 according to the present exemplary embodiment may also be used for buffering of a high-speed clock signal.

Hereinafter, a detailed description will be made of circuit configurations and operations of the first waveform adjustment section 3, the second waveform adjustment section 4, the first gate drive circuit 5, and the second gate drive circuit 6, which are characteristic portions of the signal transmission circuit 1 according to the present exemplary embodiment.

The first waveform adjustment section 3 includes an impedance element R1, a PMOS transistor Q5, and a capacitor (first capacitor) C1 which are connected in series between the power supply voltage node Vdd and the ground node Vss, (i.e., R1 and Q5 form a charging circuit for the first capacitor), an NMOS transistor Q6 connected in parallel to the capacitor C1 (i.e., Q6 is a discharging circuit for the first capacitor), and a reset control circuit 7 which controls a gate voltage of the NMOS transistor Q6.

The input signal A of the signal transmission circuit 1 is sent to a gate of the PMOS transistor Q5. The source of the PMOS transistor Q5 is connected to one end of the impedance element R1, and the drain of the PMOS transistor Q5 is connected to one end of the capacitor C1. The other end of the capacitor C1 is connected to the ground node Vss. The drain of the NMOS transistor Q6 is connected to one end of the capacitor C1, and the source of the NMOS transistor Q6 is connected to the ground node Vss. An output node B of the first waveform adjustment section 3 is connected to the drain of the PMOS transistor Q5, the drain of the NMOS transistor Q6, and one end of the capacitor C1. The first intermediate signal is output from the output node B.

The reset control circuit 7 generates a reset signal with a high level, which temporarily forces the NMOS transistor Q6 to be turned on at a predetermined time after the output signal H of the signal transmission circuit 1 changes to a high level. While the NMOS transistor Q6 is in the on-state, the capacitor C1 is discharged.

During the period when the NMOS transistor Q6 does not hold node B at Vss, the PMOS transistor Q5 is turned on when the input signal A is in a low level. Accordingly, the capacitor C1 starts charging. When the input signal A switches to a high level, the capacitor C1 stops charging, and electric charge accumulated in the capacitor C1 is discharged via the first gate drive circuit 5, and is further discharged via the NMOS transistor Q6 when the reset signal switches to a high level.

The second waveform adjustment section 4 includes a capacitor (second capacitor) C2, an NMOS transistor Q7, and an impedance element R2, which are connected in series between the power supply voltage node Vdd and the ground node Vss, (i.e., R2 and Q7 form a charging circuit for the second capacitor), a PMOS transistor Q8 connected in parallel to the capacitor C2 (i.e., Q8 is a discharging circuit for the second capacitor), and a reset control circuit 8 which controls a gate voltage of the PMOS transistor Q8.

The input signal A of the signal transmission circuit 1 is sent to the gate of the NMOS transistor Q7. The source of the NMOS transistor Q7 is connected to one end of the impedance element R2, and the drain of the PMOS transistor Q8 is connected to one end of the capacitor C2. The other end of the capacitor C2 is connected to the power supply voltage node Vdd. The source of the PMOS transistor Q8 is connected to the power supply voltage node Vdd. An output node E of the second waveform adjustment section 4 is connected to the drain of the NMOS transistor Q7, the drain of the PMOS transistor Q8, and one end of the capacitor C2. The second intermediate signal is output from the output node E.

The reset control circuit 8 generates a reset signal with a low level that temporarily forces the PMOS transistor Q8 to be turned on at a predetermined time after the output signal H of the signal transmission circuit 1 changes to a low level. While the PMOS transistor Q8 is in the on-state, the capacitor C2 is discharged.

During the time when the PMOS transistor Q8 holds node E at Vdd, the NMOS transistor Q7 is turned on when the input signal A is in a high level. Accordingly, the capacitor C2 starts charging. When the input signal A switches to a low level, the capacitor C2 stops charging, and electric charge accumulated in the capacitor C2 is released via the second gate drive circuit 6, and is further released via the NMOS transistor Q7 when the reset signal is switched to a low level.

The first gate drive circuit 5 includes a diode (first diode) D1 and two impedance elements (first and second impedance elements) R3 and R4 which are connected in series between the output node B of the first waveform adjustment section 3 and an output node of the logic inverter 2. A connection node C of the two impedance elements R3 and R4 is an output node C of the first gate drive circuit 5, which is connected to the gate of the PMOS transistor Q1. The anode of the diode D1 is connected to the output node of the first waveform adjustment section 3, and the cathode of the diode D1 is connected to one end of the impedance element R3.

The second gate drive circuit 6 includes a diode (second diode) D2 and two impedance elements (third and fourth impedance elements) R5 and R6 which are connected in series between the output node E of the second waveform adjustment section 4 and the output node of the logic inverter 2. A connection node F of the two impedance elements R5 and R6 is an output node F of the second gate drive circuit 6, and the output node F is connected to the gate of the NMOS transistor Q2. The anode of the diode D2 is connected to one end of the impedance element R5, and the cathode of the diode D2 is connected to the output node of the second waveform adjustment section 4.

The source of the PMOS transistor Q1 is connected to the power supply voltage node Vdd, and the drain of the PMOS transistor Q1 is connected to an output node H of the signal transmission circuit 1. The drain of the NMOS transistor Q2 is connected to the output node H of the signal transmission circuit 1, and the source of the NMOS transistor Q2 is connected to the ground node Vss.

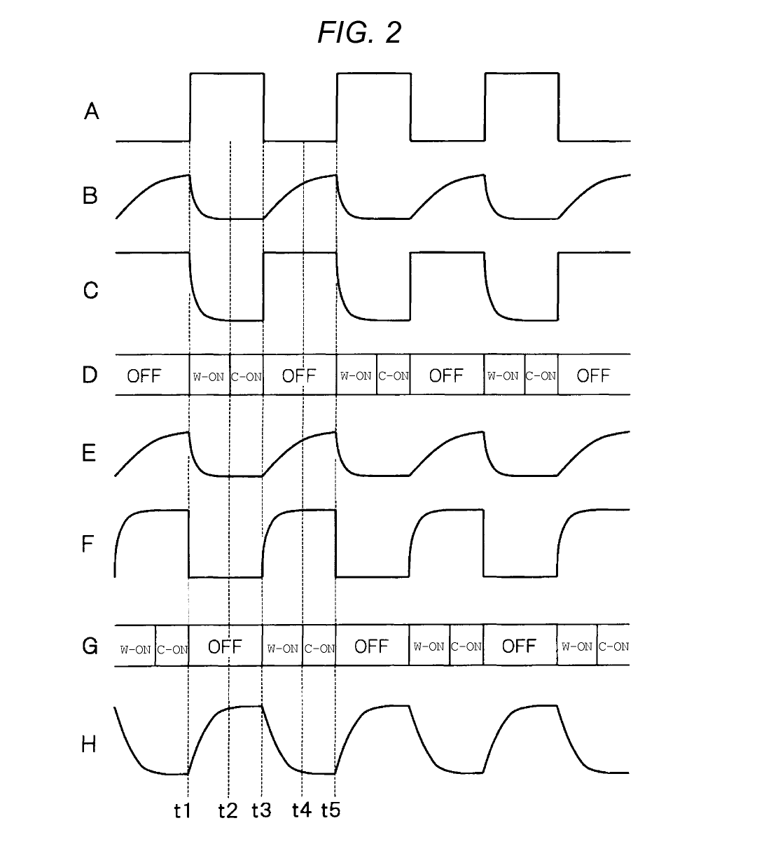

FIG. 2 is a signal waveform diagram illustrating each portion of the signal transmission circuit 1 in FIG. 1. FIG. 2 illustrates signal waveforms of an input signal A of the signal transmission circuit 1, an output signal B of the first waveform adjustment section 3, an output signal of the first gate drive circuit 5, that is, a gate signal C of the PMOS transistor Q1, an output signal E of the second waveform adjustment section 4, an output signal of the second gate drive circuit 6, that is, a gate signal F of the NMOS transistor Q2, an output signal H of the signal transmission circuit 1, and an operation state D of the PMOS transistor Q1, and an operation state G of the NMOS transistor Q2.

Hereinafter, with reference to the signal waveform diagram in FIG. 2, operation of the signal transmission circuit 1 in FIG. 1 is described. The input signal A of the signal transmission circuit 1 is a digital signal whose level repeatedly changes between a low level and a high level. At a time point t1, when the input signal A switches from a low level to a high level, the output node of the logic inverter 2 switches to a low level. Immediately before the time point t1, electric charge is accumulated in the capacitor C1 of the first waveform adjustment section 3, and the capacitor C2 of the second waveform adjustment section 4 is held discharged. Since the output node of the logic inverter 2 is in a low level, the electric charge accumulated in the capacitor C1 is discharged toward the output node of the logic inverter 2 via the first gate drive circuit 5. In addition, at a predetermined time after the time t1, a reset signal with a high level is output from the reset control circuit 7, causing further discharge of capacitor C1 to the ground node Vss via the NMOS transistor Q6.

During the discharge period (the time points t1 to t2) of the capacitor C1, the output signal C of the first gate drive circuit 5 is not a complete low voltage level, and gradually decreases towards the output of the logic inverter 2, which is at a low level. Therefore, during the discharge period of the capacitor C1, the PMOS transistor Q1 is weakly in the on-state (W-ON in FIG. 2), and the output signal H of the signal transmission circuit 1 gradually increases. In other words, the output signal H rises slowly.

After the time point t2 when the capacitor C1 finishes discharging, the output signal C of the first gate drive circuit 5 becomes a complete low voltage level, and thus the PMOS transistor Q1 is completely in the on-state (C-ON in FIG. 2). Accordingly, the output signal H of the signal transmission circuit 1 becomes a complete high voltage level. As mentioned above, a signal waveform of the output signal H of the signal transmission circuit 1 rapidly changes so as to become a final high voltage level after the time point t2.

In addition, in a period (the time points t1 to t3) when the input signal A is in a high level, the PMOS transistor Q8 of the second waveform adjustment section 4 is in the off-state, and the NMOS transistor Q7 thereof is in the on-state. Accordingly, the capacitor C2 is charged.

At the time point t3, when the input signal A switches from a high level to a low level, the output node of the logic inverter 2 switches to a high level. Accordingly, electric charge accumulated in the capacitor C2 is discharged toward the output node of the logic inverter 2 via the second gate drive circuit 6. In addition, at a predetermined time after the time t3, a reset signal with a low level is output from the reset control circuit 8, and thus the capacitor C2 is further discharged to the power supply voltage node Vdd via the PMOS transistor Q8.

During the discharge period (the time points t3 to t4) of the capacitor C2, the output signal F of the second gate drive circuit 6 is not at a complete high voltage level, and gradually increases towards the output of the logic inverter 2, which is at a high logic level. Therefore, during the discharge period of the capacitor C2, the NMOS transistor Q2 is weakly in the on-state, and the output signal H of the signal transmission circuit 1 gradually decreases. In other words, the output signal H falls slowly.

After the time point t4 when the capacitor C2 finishes discharging, the output signal F of the second gate drive circuit 6 reaches a complete high level voltage, and thus the NMOS transistor Q2 is completely in the on-state. Accordingly, the output signal H of the signal transmission circuit 1 becomes a complete low voltage level. As mentioned above, a signal waveform of the output signal H of the signal transmission circuit 1 rapidly changes so as to become a final low voltage level after the time point t4.

In addition, in a period (the time points t3 to t5) when the input signal A is in a low level, the NMOS transistor Q6 of the first waveform adjustment section 3 is in the off-state, and the PMOS transistor Q5 thereof is in the on-state. Accordingly, the capacitor C1 starts charging.

FIG. 1 illustrates an example of the signal transmission circuit 1 that buffers an input signal A, but the present exemplary embodiment is applicable to a high-speed signal bus by disposing a plurality of same circuits as in FIG. 1. In addition, the signal transmission circuit 1 in FIG. 1 is illustrated as a circuit that outputs the input signal A in positive logic, but is applicable to a circuit that inverts logic of the input signal A and outputs a result thereof, or a circuit that performs various logical operations on a plurality of input signals A and outputs a result thereof.

As mentioned above, in the present exemplary embodiment, when logic of the input signal A of the signal transmission circuit 1 is changed, a signal level of the output signal H is slowly changed in the time after the logic change occurs, and then a signal level is rapidly changed so as to be set to a final signal level. Accordingly, the time until logic of the output signal H is at a constant level may be reduced while minimizing the occurrence of harmonic noise at a rising edge and a falling edge of the output signal H. In other words, a signal delay time may be reduced. Therefore, the signal transmission circuit 1 according to the present exemplary embodiment is applicable to transmission of a high-speed signal, and may be mounted in various semiconductor chips that handle a high-speed clock since the occurrence of harmonic noise is minimized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A signal transmission circuit comprising:
an input node through which an input rectangular waveform is to be supplied;
an inverter configured to receive the input signal and generate an inverted input signal therefrom;
a push-pull circuit connected between first and second reference voltage nodes, the push-pull circuit having first and second inputs and configured to generate an output signal of the signal transmission circuit;
a first drive circuit connected to the inverter and the first input of the push-pull circuit, and configured to receive the inverted input signal and a first adjusted waveform and generate a first drive signal supplied to the first input, wherein the first adjusted waveform falls with a first time constant during a portion of a high time of the input rectangular waveform; and
a second drive circuit connected to the inverter and the second input of the push-pull circuit and configured to receive the inverted input signal and a second adjusted waveform and generate a second drive signal supplied to the second input, wherein the second adjusted waveform rises with a second time constant during a portion of a low time of the input rectangular waveform,
wherein the output signal of the signal transmission circuit has a rise time correlated to the first adjusted waveform and a fall time correlated to the second adjusted waveform.

2. The signal transmission circuit according to claim 1,
wherein the push-pull circuit includes a first MOS transistor and a second MOS transistor connected in series between the first and second reference voltage nodes,
wherein the source of the first MOS transistor is connected to the drain of the second MOS transistor to form an output node at which the output signal is generated, and
wherein the first input of the push-pull circuit is a gate of the first MOS transistor and the second input of the push-pull circuit is a gate of the second MOS transistor.

3. The signal transmission circuit according to claim 1, further comprising:
a first waveform adjustment circuit that includes a first charging circuit, a first discharging circuit, and a first capacitor,
a second waveform adjustment circuit that includes a second charging circuit, a second discharging circuit, and a second capacitor,
wherein the first charging circuit charges the first capacitor to a first voltage during a low time of the input rectangular waveform, and the first discharging circuit discharges the first capacitor towards the output of the inverter during a portion of the time when the output signal of the transmission circuit is high, and
wherein the second charging circuit charges the second capacitor to a second voltage during a low time of the input rectangular waveform, and wherein the second discharging circuit discharges the second capacitor towards the output of the inverter during a portion of the time when the output signal of the transmission circuit is low.

4. The signal transmission circuit according to claim 3,
wherein the first discharging circuit includes a first reset control circuit and a first transistor connected in parallel with the first capacitor,
wherein the first reset control circuit is connected between the output and a gate of the first transistor,
wherein the first reset control circuit discharges the first capacitor during a portion of time when the output signal is high,
wherein the second discharging circuit includes a second reset control circuit and a second transistor connected in parallel with the second capacitor,
wherein the second reset control circuit is connected between the output and a gate of the second transistor, and
wherein the second reset control circuit discharges the second capacitor during a portion of time when the output signal is low.

5. The signal transmission circuit according to claim 3,
wherein the first drive circuit includes a first diode and first and second resistors connected in series,
wherein an anode of the first diode is connected to the output of the first waveform adjustment circuit, the second resistor is connected to the output of the inverter, and a junction of the first and second resistors is connected to the first input of the push-pull circuit,
wherein the second drive circuit includes a second diode and third and fourth resistors connected in series, and
wherein a cathode of the second diode is connected to the output of the second waveform adjustment circuit, the second resistor is connected to the output of the inverter, and a junction of the third and fourth resistors is connected to the second input of the push-pull circuit.

6. A signal transmission circuit comprising:
a logic inverter connected between first and second reference voltage nodes and configured to generate an inverted input waveform from an input rectangular waveform;
a push-pull circuit having first and second inputs, the push-pull circuit connected between the first and second reference voltage nodes and configured to generate an output signal of the signal transmission circuit;
a first waveform adjustment circuit configured to generate a first adjusted waveform from the output signal;
a second waveform adjustment circuit configured to generate a second adjusted waveform from the output signal;
a first drive circuit connected to receive the first adjusted waveform from the first waveform adjustment circuit and the inverted input waveform, and configured to generate a first drive signal supplied to the first input of the push-pull circuit; and
a second drive circuit connected to receive the second adjusted waveform from the second waveform adjustment circuit and the inverted input waveform, and configured to generate a second drive signal supplied to the second input of the push-pull circuit.

7. The signal transmission circuit according to claim 6,
wherein the push-pull circuit includes a first MOS transistor and a second MOS transistor connected in series between the first and second reference voltage nodes,
wherein the source of the first MOS transistor is connected to the drain of the second MOS transistor to form an output node at which the output signal is generated, and
wherein the first input of the push-pull circuit is a gate of the first MOS transistor and the second input of the push-pull circuit is a gate of the second MOS transistor.

8. The signal transmission circuit according to claim 6,
wherein the first waveform adjustment circuit includes a charging circuit, a discharging circuit, and a capacitor,
wherein the charging circuit charges the capacitor to a first voltage during a low time of the input rectangular waveform, and
wherein the discharging circuit discharges the charged capacitor towards the output of the inverter during a portion of the time when the output signal of the transmission circuit is high.

9. The signal transmission circuit according to claim 6,
wherein the second waveform adjustment circuit includes a charging circuit, a discharging circuit, and a capacitor,
wherein the charging circuit charges the capacitor to a second voltage during a high time of the input rectangular waveform, and
wherein the discharging circuit discharges the capacitor towards the output of the inverter during a portion of the time when the output signal of the transmission circuit is low.

10. The signal transmission circuit according to claim 6,
wherein the first drive circuit includes a diode and a first and second resistor connected in series, and
wherein an anode of the diode is connected to the output of the first waveform adjustment circuit, the second resistor is connected to the output of the logic inverter, and a junction of the first and second resistor is connected to the first input of the push-pull circuit.

11. The signal transmission circuit according to claim 10,
wherein the second drive circuit includes a diode and a first and second resistor connected in series, and
wherein a cathode of the diode is connected to the output of the second waveform adjustment circuit, the second resistor is connected to the output of the logic inverter, and a junction of the first and second resistor is connected to the second input of the push-pull circuit.

12. A method of driving first and second inputs of a push-pull circuit that generates an output waveform, the method comprising:
inverting an input rectangular waveform to generate an inverted input waveform;
generating a first adjusted waveform based on the output waveform;
generating a second adjusted waveform based on the output waveform;
generating a first drive signal based on the first adjusted waveform and the inverted input waveform and supplying the first drive signal to the first input, wherein the first drive signal falls with a first time constant during a portion of time when the input rectangular waveform is high; and
generating a second drive signal based on the second adjusted waveform and the inverted input waveform and supplying the second drive signal to the second input, wherein the second drive signal rises with a second time constant during a portion of time when the input rectangular waveform is low,
wherein the output waveform rises with a rate correlated to the first time constant and falls with a rate correlated to the second time constant.

13. The method according to claim 12, wherein generating the first adjusted waveform includes discharging a capacitor to a low level of the inverted input waveform according to the first time constant.

14. The method according to claim 13, wherein generating the first adjusted waveform includes charging the capacitor during the time during a portion of time when the input rectangular waveform is low.

15. The method according to claim 12, wherein generating the second adjusted waveform includes discharging a capacitor to a high level of the inverted input waveform according to the second time constant.

16. The method according to claim 15, wherein generating the first adjusted waveform includes charging the capacitor during a portion of the time when the input rectangular waveform is high.

17. The method according to claim 12, wherein the push-pull circuit includes a first MOS transistor and a second MOS transistor connected in series between first and second reference voltage nodes and the first input of the push-pull circuit is a gate of the first MOS transistor and the second input of the push-pull circuit is a gate of the second MOS transistor.
